(19) United States
(12) Patent Application Publication
(10) Pub. No.: US 2008/0001240 A1
(43) Pub. Date: Jan. 3, 2008

(54) Solid state image pickup device, method for manufacturing the same, semiconductor device and method for manufacturing the same

(76) Inventors: Masanori Minamio, Osaka (JP); Tetsumasa Maruo, Osaka (JP); Kiyokazu Itoi, Kyoto (JP); Toshiyuki Fukuda, Kyoto (JP)

Correspondence Address: MCDERMOTT WILL & EMERY LLP, 600 13TH STREET, NW, WASHINGTON, DC, 20005-3096, US

(21) Appl. No.: 11/710,571

(22) Filed: Feb. 26, 2007

(30) Foreign Application Priority Data
Jun. 30, 2006 (JP) 2006-181997
Dec. 19, 2006 (JP) 2006-341530

(51) Int. Cl. H01L 31/0203; H01L 21/00

(52) U.S. Cl. 257/434; 438/64; 257/E21.001; 257/E31.117

(57) ABSTRACT

A solid state image pickup device 1 includes a substrate 10 on which a solid state image pickup element 14 is mounted and a transparent component 11. A polymerization initiator for bonding the substrate 10 and the transparent component 11 is onium salt having a halogen-containing aromatic compound as an anion.

### CROSS-REFERENCE TO RELATED APPLICATION

This non-provisional application claims priority under 35 U.S.C. § 119(a) of Japanese Patent Application No. 2006-341530 filed in Japan on Dec. 19, 2006, the entire contents of which are hereby incorporated by reference.

### BACKGROUND OF THE INVENTION

1. Field of the Invention

The present invention relates to a solid state image pickup device including a solid state image pickup element placed in a housing and a method for manufacturing the same, as well as a semiconductor device including a semiconductor element placed in a housing and a method for manufacturing the same.

2. Description of Related Art

A conventional solid state image pickup device, such as a CCD or a CMOS, includes a solid state image pickup element placed in a cavity of a package body, a transparent component arranged to cover the cavity and a resin adhesive for bonding the transparent component to the package body (for example, see Japanese Unexamined Patent Publication No. H10-321749). This structure is also applicable to semiconductor devices including sound sensor elements, pressure sensor elements, acceleration sensor elements, laser elements, LEDs or photodiodes as semiconductor elements.

In this structure, the solid state image pickup element is bonded to a surface in the cavity of the package body by die bonding. Connection terminals of the package body and Al electrodes of the solid state image pickup element are connected by wire bonding, and then the cavity is covered with the transparent component. The transparent component is bonded to the package body using a resin adhesive. The resin adhesive is generally a thermosetting resin or a UV curable resin.

On the surface of the solid state image pickup element, lenses made of an acrylic resin called on-chip lenses are formed to enhance light gathering efficiency. However, the on-chip lenses have a problem of heat resistance. To be more specific, the microlenses are softened and deformed when heat is applied thereto for a long time. Therefore, it is necessary to cure the resin adhesive in a short time at low temperature as possible. From this point of view, the UV curable resin is preferably used. The UV curable resin is receiving attention from the aspect of working efficiency.

As the solid state image pickup element is enclosed in the cavity of the package body, humidity mixed into the cavity from outside may possibly be condensed on the inner surface of the transparent component, or alternatively, wires of the solid state image pickup element may be corroded. To eliminate these drawbacks, a hygroscopic resin is arranged in the cavity to adsorb the humidity (for example, see Japanese Unexamined Patent Publication 2004-22928).

Further, as a polymerization initiator contained in the UV curable resin, various kinds of onium salts have been considered, for example, iodonium salt, sulfonium salt and phosphonium salt. A system containing the onium salt is stable at room temperature and shows high reaction rate when heated or exposed to light. However, since the onium salt is an acidic substance, a resin cured using the onium salt gives an acidic extract in a moisture resistance test. This is because the onium salt remaining in the cured resin adhesive is liberated from the resin in the presence of humidity, thereby corroding the electronic parts. Accordingly, it has been proposed to add an alkaline filler to the resin in order to neutralize the resin and prevent the corrosion (for example, see Japanese Unexamined Patent Publication No. 2000-264955).

### SUMMARY OF THE INVENTION

According to Japanese Unexamined Patent Publication H10-321749 described above, a compound liberated from the resin adhesive is not taken into account. Therefore, under high temperature and high humidity condition, the compound liberated from the resin adhesive brings about corrosion of the wires of the solid state image pickup element. As a result, the Al electrodes of the solid state image pickup element may be corroded or the connection between the Al electrodes and Au wires may become deteriorated.

According to Japanese Unexamined Patent Publication No. 2004-22928, the hygroscopic substance placed in the cavity of the package body adsorbs humidity even if it is mixed into the cavity. Therefore, the condensation on the inner surface of the transparent component is prevented. However, ionic substances and gases liberated from the resin adhesive cannot be adsorbed. Further, according to Japanese Unexamined Patent Publication No. 2000-264955, it is considered that the alkaline filler is able to neutralize the onium salt liberated from the cured resin adhesive. However, depending on the combination of a cation and an anion in the onium salt, reliability of the solid state image pickup device may significantly be impaired by the cation and the anion liberated from the onium salt.

The present invention has been achieved to solve the above-described problems. An object of the present invention is to provide a solid state image pickup device capable of preventing the corrosion of an alloy layer formed on an interface between Au wires and Al electrodes even under high temperature and high humidity condition.

In order to achieve the above-described object, a first solid state image pickup device of the present invention includes: a solid state image pickup element including an image pickup region and a plurality of bonding pads; a substrate having a recess and containing the solid state image pickup element; a plurality of connection terminals formed in the recess of the substrate; Au wires for electrically connecting the bonding pads and the connection terminals; a transparent component placed on a top surface of the substrate; and a resin adhesive for bonding the substrate and the transparent component, wherein the resin adhesive contains an epoxy resin, a polymerization initiator and organic peroxide and the polymerization initiator contains onium salt having a halogen-containing aromatic compound as an anion.

According to this configuration, substances in the resin adhesive for bonding the transparent component and the substrate are prevented from liberating from the resin adhesive even if the solid state image pickup device is present in high temperature and high humidity environment. Therefore, the solid state image pickup device is provided with high reliability.

In order to achieve the above-described object, a second solid state image pickup device of the present invention includes: a solid state image pickup element including an image pickup region and a plurality of bonding pads; a substrate on which the solid state image pickup element is mounted; a rib formed on the substrate; a plurality of connection terminals formed on the substrate; Au wires for electrically connecting the bonding pads and the connection terminals; a transparent component placed above the substrate and bonded to a top surface of the rib; and a resin adhesive for bonding the top surface of the rib and the transparent component, wherein the resin adhesive contains an epoxy resin, a polymerization initiator and organic peroxide and the polymerization initiator contains onium salt having a halogen-containing aromatic compound as an anion.

With this configuration, there is no need of using a substrate which is prepared by a complicated fabrication process. Therefore, the solid state image pickup device is provided at lower cost.

With respect to the above-described configurations, it is preferable that the halogen-containing aromatic compound is a fluorine-containing aromatic compound.

With this configuration, the reaction rate is increased and halogen is less likely to be liberated from the cured resin adhesive. Therefore, the solid state image pickup device is provided with high reliability.

With respect to the above-described configurations, it is preferable that the halogen-containing aromatic compound is a borate compound.

Further, it is preferable that the content of the polymerization initiator in the resin adhesive is higher than 0.5 wt % and less than 7 wt %.

With this configuration, the content of the polymerization initiator remains unreacted in the cured adhesive resin is reduced and the substances in the cured resin adhesive are less likely to be liberated. Therefore, the solid state image pickup device is provided with high reliability.

With respect to the above-described configurations, it is preferable that the bonding pads of the solid state image pickup element are Al electrodes and the ratio of an alloy formed on an interface between the Au wires and the Al electrodes is 50% or higher.

With this configuration, the solid state image pickup device is provided with great safety against the corrosion of an Au—Al alloy formed on the interface between the Au wires and the Al electrodes.

With respect to the above-described configurations, it is preferable that the substrate is a ceramic substrate.

Since the ceramic substrate is less hygroscopic and capable of reducing the amount of humidity mixed into the cavity of the substrate, the solid state image pickup device is provided with high reliability.

With respect to the above-described configurations, it is preferable that the substrate is a resin substrate using glass fabric epoxy or aramid as a base material.

Since the resin substrate is lighter in weight than the ceramic substrate, the weight of the solid state image pickup device is reduced. This contributes to weight reduction of mobile devices.

### BRIEF DESCRIPTION OF THE DRAWINGS

FIG. 1A is a schematic perspective view illustrating the structure of a solid state image pickup device of a first embodiment of the present invention and FIG. 1B is a schematic perspective view illustrating the inside structure thereof.

FIG. 2A is a schematic plan view partially broken away and FIG. 2B is a sectional view taken along the line A-A shown in FIG. 2A.

FIGS. 3A to 3E are flow diagrams illustrating a method for manufacturing the solid state image pickup device of the first embodiment of the present invention.

FIG. 4A is a schematic sectional view illustrating the vicinity of an Al electrode of the solid state image pickup device of the first embodiment of the present invention and FIG. 4B is a schematic sectional view taken along the line B-B shown in FIG. 4A.

FIG. 5A is a schematic perspective view illustrating the structure of a solid state image pickup device of a second embodiment of the present invention and FIG. 5B is a schematic perspective view illustrating the inside structure thereof.

FIG. 6A is a schematic plan view of the solid state image pickup device of the second embodiment of the present invention and FIG. 6B is a sectional view taken along the line C-C shown in FIG. 6A.

FIGS. 7A to 7F are flow diagrams illustrating a method for manufacturing the solid state image pickup device of the second embodiment of the present invention.

FIG. 8A is a schematic perspective view illustrating a semiconductor device of a third embodiment of the present invention with a cover detached and FIG. 8B is a schematic perspective view of the same with the cover attached.

FIG. 9A is a schematic plan view, partially broken away, of a semiconductor device of a fourth embodiment of the present invention and FIG. 9B is a sectional view taken along the line A-A shown in FIG. 9A.

FIG. 10A is a schematic plan view, partially broken away, of a semiconductor device of a fifth embodiment of the present invention and FIG. 10B is a sectional view taken along the line C-C shown in FIG. 10A.

### DETAILED DESCRIPTION OF THE INVENTION

Hereinafter, explanation of embodiments of the present invention is provided with reference to the drawings. In the drawings, the thicknesses and lengths of components depicted are different from actual ones for convenience sake. The same is applied to the number of electrodes and terminals of the components. Further, materials for the components are not limited to those described below.

### First Embodiment

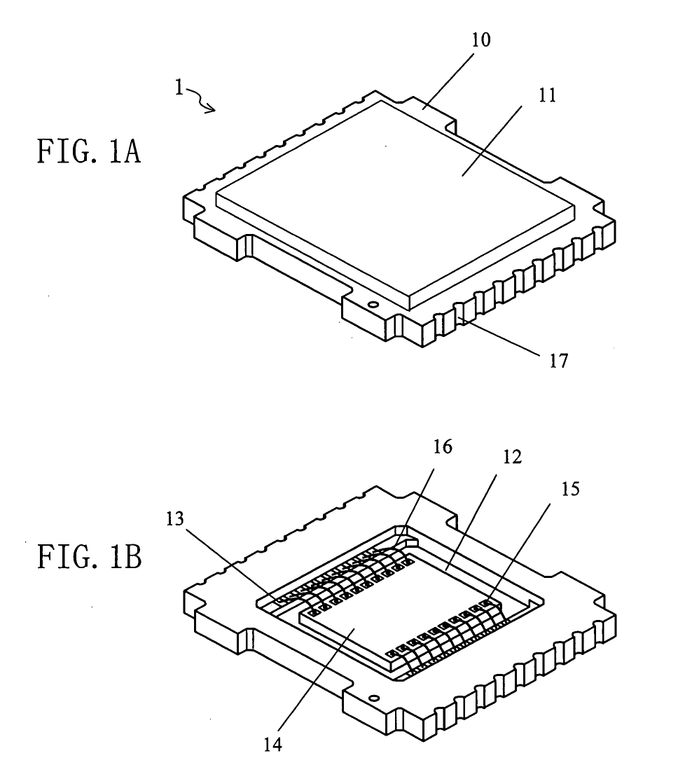

FIG. 1A is a schematic perspective view illustrating a solid state image pickup device 1 of a first embodiment and FIG. 1B is a schematic perspective view illustrating the solid state image pickup device 1 of FIG. 1A from which a transparent component 11 and a resin adhesive are removed.

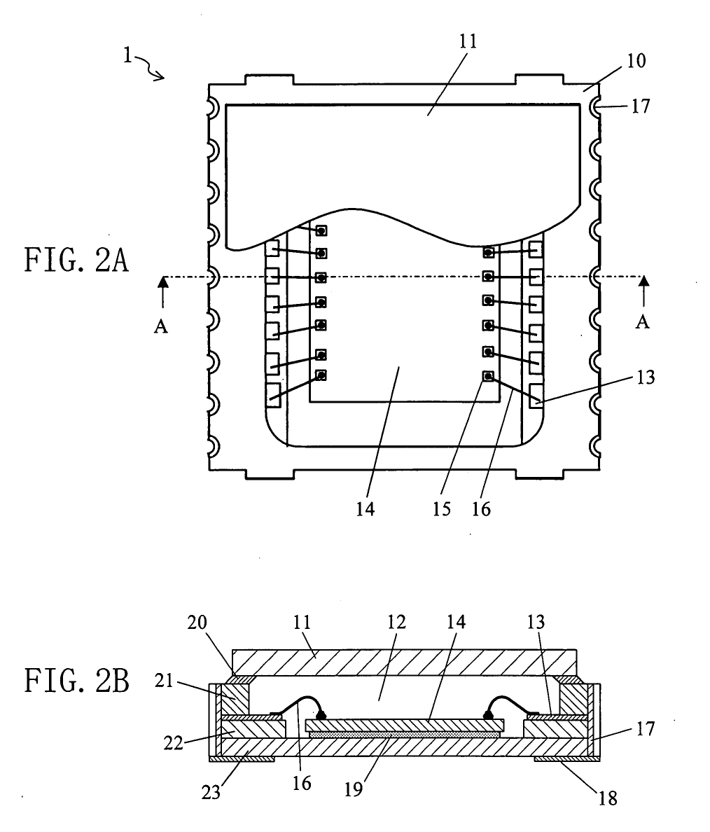

FIG. 2A is a schematic plan view of the solid state image pickup device 1 of the present embodiment and FIG. 2B is a sectional view taken along the line A-A of FIG. 2A.

The solid state image pickup device 1 of the present embodiment includes a recessed substrate 10 having a cavity 12 in the middle portion thereof. The substrate 10 includes a plurality of connection terminals 13 formed on the top surface of an intermediate layer 22 exposed in the cavity 12, a plurality of external side electrodes 17 formed on the end faces of the substrate 10 and a plurality of external bottom electrodes 18 formed on the bottom surface of the substrate 10. The solid state image pickup device 1 further includes a solid state image pickup element 14 having a plurality of Al electrodes 15, Au wires 16 for electrically connecting the connection terminals 13 formed on the intermediate layer 22 of the substrate 10 and the Al electrodes (bonding pads) 15, a transparent component 11 covering the cavity 12 of the substrate 10 and a resin adhesive 20 for bonding a topmost layer 21 of the substrate 10 and the transparent component 11.

The substrate 10 is made of the intermediate layer 22 and the topmost layer 21 which are frame-shaped and stacked on the periphery of a substantially rectangular bottommost layer 23. Space enclosed with the intermediate layer 22 and the topmost layer 21 is the cavity 12. The topmost layer 21 is provided on the periphery of the intermediate layer 22. That is, the bottommost to topmost layers 23 to 21 are stacked in the form of a staircase. The transparent component 11 is fixed onto the top surface of the topmost layer 21 to cover the cavity 12, i.e., on the top surface of the substrate 10.

This package has a so-called LCC (leadless chip carrier) structure, which is one of the packages reduced in size and thickness.

In the present embodiment, the substrate 10 is a ceramic substrate.

The ceramic substrate 10 includes three insulating ceramic layers. The ceramic material may be a sintered body of alumina or aluminum nitride or a sintered body of glass-added ceramic material obtained by low-temperature firing. Alternatively, a resin material added with ceramic powder may be molded into the substrate. If high heat transfer property is required, the sintered body of ceramic material such as alumina is preferably used.

The connection terminals 13 may be obtained by forming a copper layer on the top surface of the intermediate layer 22 of the substrate 10 by a combined use of electroless plating and electroplating and patterning the copper layer into desired shape by etching. Alternatively, the connection terminals 13 may be formed by printing using Cu paste, Ag paste or W paste.

The external side electrodes 17 are in the form of halves of through holes penetrating the substrate 10 from the top surface to the bottom surface thereof. The external side electrodes 17 may be obtained by forming a copper layer on semicircular recesses by a combined use of electroless plating and electroplating and patterning the copper layer into desired shape by etching. Alternatively, the external side electrodes 17 may be formed by printing using metal paste such as Cu paste, Ag paste or W paste.

The external bottom electrodes 18 may be obtained by forming a copper layer on the bottom surface of the bottommost layer 23 of the substrate 10 by a combined use of electroless plating and electroplating and patterning the copper layer into desired shape by etching. Alternatively, the external bottom electrodes 18 may be formed by printing using metal paste such as Cu paste, Au paste or W paste.

The external side electrodes 17 are connected to the connection terminals 13 at the semicircular recesses formed in the end faces of the substrate 10. The Al electrodes 15 of the solid state image pickup element 14 are connected to the connection terminals 13 with the Au wires 16. The connection terminals 13 are electrically connected to the external side electrodes 17 and the external bottom electrodes 18.

It is preferable to form a thin gold film (not shown) on the surfaces of the connection terminals 13, external side electrodes 17 and external bottom electrodes 18. The thin gold film may preferably be provided by forming a nickel plating layer on the thick copper plating wires and forming a thin gold film thereon by plating. By so doing, ball bonding of the Au wires to the connection terminals 13 is performed with improved bondability. Further, during the soldering of the solid state image pickup device 1 to a mother board, the external side electrodes 17 and the external bottom electrodes 18 show improved wettability, thereby enhancing the reliability of the soldered joints. The connection terminals, external side electrodes and external bottom electrodes may be formed by printing and baking W paste and then forming a Ni plating layer and an Au plating layer thereon.

The solid state image pickup element 14 is bonded to the bottom surface of the cavity 12 of the substrate 10 with a die bonding agent 19. Examples of the die bonding agent 19 include thermosetting resin paste such as an epoxy resin and a polyimide resin and an adhesive tape made of an epoxy resin or a polyimide resin. If high heat transfer property is required, it is preferable to use resin paste with a metallic filler such as Ag dispersed therein.

The resin adhesive 20 may be a thermosetting resin or a UV curable resin. In particular, the UV curable resin is preferable because it cures at a lower temperature in a shorter time as compared with the thermosetting resin and less likely to cause thermal damage to the solid state image pickup element 14, especially to the on-chip lenses formed on an image pickup region of the solid state image pickup element 14. Further, cycle time of the manufacture is reduced.

The resin adhesive 20 used in the present embodiment contains an epoxy resin [A], a polymerization initiator [B], organic peroxide [C] and a filler [D].

Examples of the epoxy resin [A] include bisphenol epoxy resins, novolac epoxy resins and biphenyl epoxy resins. Among the bisphenol epoxy resins, a bisphenol A epoxy resin, a bisphenol S epoxy resin and a bisphenol F epoxy resin are preferable and generally used because they are in the liquid state at room temperature.

The polymerization initiator [B] according to the present embodiment is onium salt containing a cation and an anion. Examples of the onium cation include iodonium, sulfonium, selenonium, phosphonium and ammonium. The onium anion is preferably a halogen-containing aromatic compound. Due to covalent bonding of halogen and aromatic carbon, the onium salt is less likely to dissociate even at high temperature and high humidity and the cured resin is improved in stability. Even if liberated halogen ions corrode the Al electrodes or iodonium salt is used as the cation of the onium salt, separation of iodine is prevented. Thus, secondary effect such as corrosion of Au is also prevented. In particular, onium salt containing a fluorine-containing aromatic compound as the anion is preferable because it is stable and increases the cure rate.

The halogen-containing aromatic compound may be a borate compound. Suitable examples thereof include diphenyliodonium tetrakis(pentafluorophenyl)borate, bis(p-octadecylphenyl)iodonium tetrakis(pentafluorophenyl)borate, bis(p-octadecyloxyphenyl)iodonium tetrakis(pentafluorophenyl)borate, phenyl(p-octadecyloxyphenyl)iodonium tetrakis(pentafluorophenyl)borate, diphenyliodonium tetrafluoroborate, diphenyliodonium hexafluorophosphonate, diphenyliodonium hexafluoroarsenate, diphenyliodonium trifluoromethanesulfonate, diphenyliodonium trifluoroacetate, diphenyliodonium-p-toluenesulfonate, 4-methoxyphenylphenyliodonium tetrafluoroborate, 4-methoxyphenylphenyliodonium hexafluorophosphonate, 4-methoxyphenylphenyliodonium hexafluoroarsenate, 4-methoxyphenylphenyliodonium trifluoromethane, dimethyl(benzyl)sulfonium tetrakis[3,5-bis(trifluoromethyl)phenyl]borate, dimethyl(p-bromobenzyl)sulfonium tetrakis[3,5-bis(trifluoromethyl)phenyl]borate, dimethyl(p-cianobenzyl)sulfonium tetrakis[3,5-bis(trifluoromethyl)phenyl]borate, dimethyl(m-nitrobenzyl)sulfonium tetrakis[3,5-bis(trifluoromethyl)phenyl]borate, dimethyl(pentafluorophenylmethyl)sulfonium tetrakis[3,5-bis(trifluoromethyl)phenyl]borate, dimethyl(p-(trifluoromethyl)benzyl)sulfonium tetrakis[3,5-bis(trifluoromethyl)phenyl]borate, dimethyl(p-(methylsulfonylbenzyl)sulfonium tetrakis[3,5-bis(trifluoromethyl)phenyl]borate, dimethyl(o-acetylbenzyl)sulfonium tetrakis[3,5-bis(trifluoromethyl)phenyl]borate, dimethyl(o-benzoylbenzyl)sulfonium tetrakis[3,5-bis(trifluoromethyl)phenyl]borate, dimethyl(p-isopropylbenzyl)sulfonium tetrakis[3,5-bis(trifluoromethyl)phenyl]borate, dimethyl(p-methoxybenzyl)sulfonium tetrakis[3,5-bis(trifluoromethyl)phenyl]borate, dimethyl(2-naphthylmethyl)sulfonium tetrakis[3,5-bis(trifluoromethyl)phenyl]borate, dimethyl(9-anthrylmethyl)sulfonium tetrakis[3,5-bis(trifluoromethyl)phenyl]borate, diethyl(benzyl)sulfonium tetrakis[3,5-bis(trifluoromethyl)phenyl]borate, methylethyl(benzyl)sulfonium tetrakis[3,5-bis(trifluoromethyl)phenyl]borate, methylphenyl(benzyl)sulfonium tetrakis[3,5-bis(trifluoromethyl)phenyl]borate and diphenyl(benzyl)sulfonium tetrakis[3,5-bis(trifluoromethyl)phenyl]borate.

The content of the polymerization initiator in the resin adhesive is preferably higher than 0.5 wt % and less than 7.0 wt %. If the content is 7.0 wt % or higher, the polymerization occurs abruptly and adhesion between the resin adhesive and the transparent component is reduced. Further, if the content is 0.5 wt % or lower, the polymerization does not occur sufficiently and the adhesion is reduced.

Examples of the organic peroxide [C] of the present embodiment include aliphatic, alicyclic and aromatic organic peroxides. Suitably used are 1,1-bis(t-butylperoxy) 3,3,5-trimethylcyclohexane and t-butylperoxy benzonate.

The filler [D] of the present embodiment may be an inorganic filler such as talc, mica, Al₂O₃, MgO, BN, AlN or SiO₂. The filler alleviates thermal distortion at the joints between different materials used to form the package. Therefore, the filler is used to reduce the difference in linear expansion coefficient between the adhesive and the adherend component.

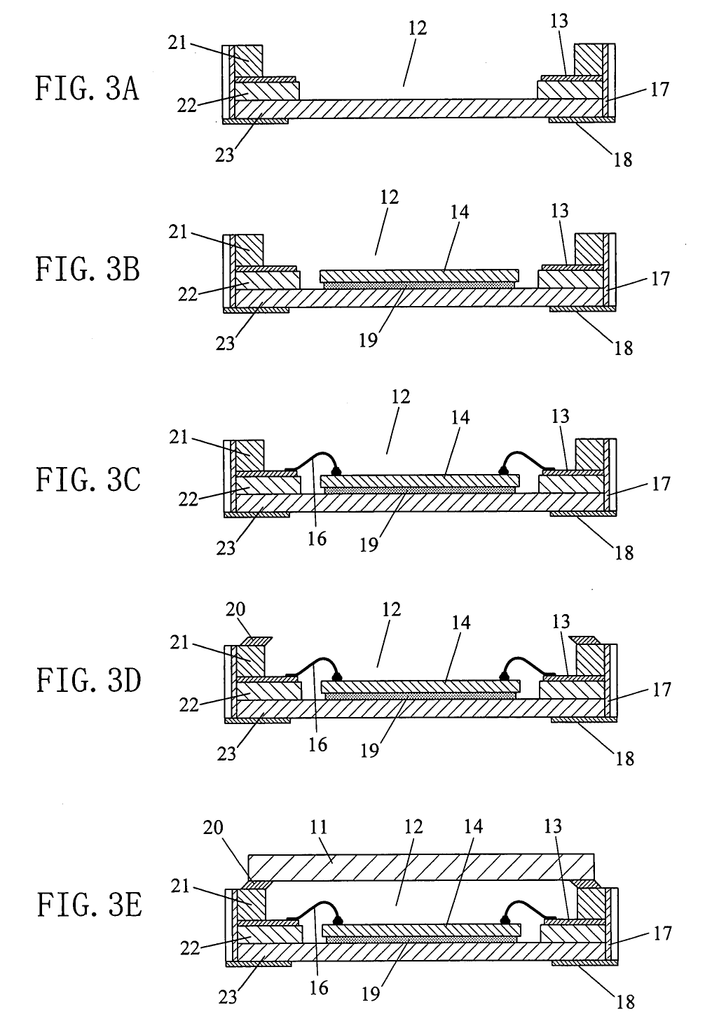

Hereinafter, brief explanation of a method for manufacturing the solid state image pickup device of the present embodiment is provided with reference to FIGS. 3A to 3E.

Referring to FIG. 3A, a die bonding agent 19 is applied to the middle of the bottom surface of the cavity 12 (the top surface of the bottommost layer 23) of the substrate 10 using a dispenser. The dispenser may have a single nozzle or multiple nozzles. The die bonding agent 19 may be applied by a transfer method such as stamping. The die bonding agent 19 may be thermosetting paste containing a thermosetting resin such as an epoxy resin or a polyimide resin as a main ingredient. The epoxy resin may preferably be bisphenol epoxy resins, novolac epoxy resins or biphenyl epoxy resins. Among the bisphenol epoxy resins, a bisphenol A epoxy resin, a bisphenol S epoxy resin and a bisphenol F epoxy resin are preferable and generally used because they are in the liquid state at room temperature. If high heat transfer property is required, it is preferable to use resin paste with a metallic filler such as Ag dispersed therein. The thermosetting resin paste may be replaced with an adhesive tape containing the thermosetting resin such as the epoxy resin or the polyimide resin as a main ingredient. The adhesive tape is bonded to the rear surface of a wafer before separating the solid state image pickup elements 14 by dicing such that it is cut together with the solid state image pickup elements 14. In this way, the solid state image pickup elements 14 are provided with the adhesive tape bonded to the rear surface.

As shown in FIG. 3B, the solid state image pickup element 14 is placed in the middle of the cavity 12 of the substrate 10. This is stored in a thermosetting oven at about 120 to 170° C. for 2 hours such that the die bonding agent 19 is cured by heat. The thermal curing may preferably be carried out in nitrogen atmosphere from the aspect of preventing surface oxidation of the Al electrodes 15 of the solid state image pickup element 14.

Then, as shown in FIG. 3C, the Al electrodes 15 of the solid state image pickup element 14 are connected to the connection terminals 13 of the substrate 10 with the Au wires 16 by ball bonding. The connection may be achieved by wedge bonding instead of the ball bonding and the Au wires may be replaced with Al or Cu wires. In this way, the Al electrodes 15 of the solid state image pickup element 14, Au wires 16, connection terminals 13, external side electrodes 17 and external bottom electrodes 18 are electrically connected.

Then, as shown in FIG. 3D, a resin adhesive 20 is applied to the top surface of the topmost layer 21 of the substrate 10 using a dispenser.

Thereafter, as shown in FIG. 3E, a transparent component 11 is placed on the topmost layer 21 of the substrate 10 such that the cavity 12 of the substrate 10 is covered with the transparent component 11.

Subsequently, preliminary heating is carried out under certain conditions to temporarily fix the transparent component 11 onto the substrate 10 and then the top surface of the transparent component 11 is irradiated with UV light. The UV light irradiation initiates the polymerization of the resin adhesive 20, thereby curing the resin adhesive 20 and bonding the transparent component 11 to the substrate 10. The UV light preferably has a wavelength of 300 nm or higher and illumination of 200 mW or higher.

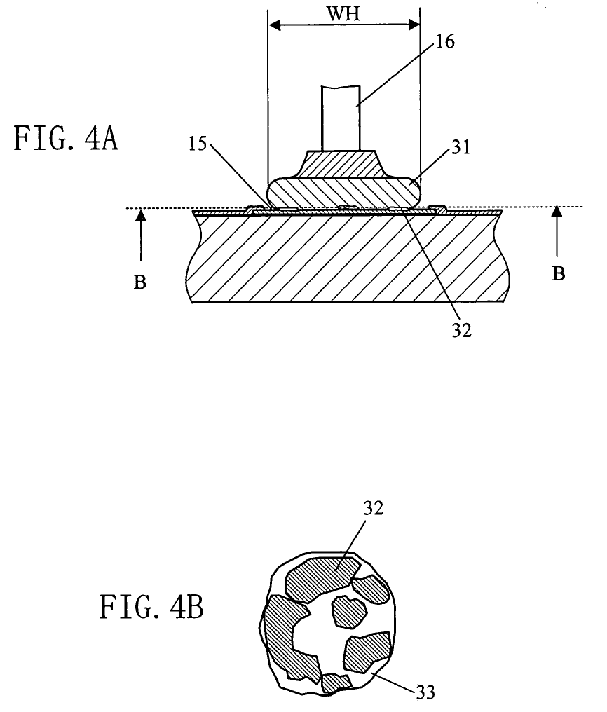

FIG. 4A is a schematic sectional view illustrating the joint between the Al electrode 15 of the solid state image pickup element 14 and the Au wire 16. According to an Au ball bonding method, the tips of the Au wires 16 are molten in advance and shaped into balls. The balls are then pressed onto the Al electrodes 15 while ultrasonic and thermal energies are applied thereon to create welds. As a result, the balls are shaped into flat nail heads 31. The diameter WH of the nail head 31 becomes larger than that of the Au wire 16. If the Au wire 16 has a diameter of 22.5 to 25.0 μm, the nail head 31 has a diameter WH of (40 to 95)±10 μm. According to this process, a natural oxide film formed on the Al electrodes 15 is torn and the Au wires are brought into contact with the new Al surface. Thus, an Au—Al alloy layer 32 is formed.

In the Au ball bonding method, the output of ultrasonic energy, bonding load and bonding temperature are varied to control the ratio of the alloy formed.

FIG. 4B is a schematic cross sectional view taken along the line B-B shown in FIG. 4A. The Au—Al alloy 32 may be made of Au₄Al. Referring to the cross sectional view, the ratio of the area occupied by the Au—Al alloy 32 contributes to the mechanical strength of the Al wires 16 and the Al electrodes 15. That is, the mechanical strength of the Al wires 16 and the Al electrodes 15 increases as the ratio of the alloy area increases. The area of the Au—Al alloy 32 and that of unalloyed part 33 of the nail head are calculated by image analysis using an X-ray diffraction photograph of the vicinity of the Al electrode taken from above. Then, by the following equation, the ratio of the Au—Al alloy is calculated and referred to as a parameter of the mechanical strength.

### The alloy ratio (%)=100×(Au—Al alloy area)/(nail head contacting area)

### EXAMPLES

In the following examples, a fluid bisphenol F epoxy resin was used as the epoxy resin [A] of the resin adhesive 20.

The polymerization initiators [B] used were:

B-1: diaryliodonium tetrakis(pentafluorophenyl)borate;

B-2: diaryliodonium hexafluoroantimonate;

B-3: triarylsulfonium hexafluoroantimonate; and

B-4: triarylsulfonium tetrakis(pentafluorophenyl)borate.

1,1-bis(t-butylperoxy)3,3,5-trimethylcyclohexane was used as the organic peroxide [C] and talc was used as the filler [D].

The evaluation was performed in the following manner.

### (1) THB Test

The solid state image pickup element 14 was mounted on the substrate 10 and the transparent component 11 was bonded to the substrate 10 with the resin adhesive 20. The resin adhesive 20 was irradiated with UV light of 365 nm with 15 J and heated at 120° C. for 10 minutes to cure. Thus, the solid state image pickup device 1 was fabricated. Bias voltage of 12.5 V was applied to the solid state image pickup element 14 in 85° C. and 85% RH environment and an electric test was performed every 200 hours. In Table 1, the cumulative sum of failed solid state image pickup elements 14 is indicated as a numerator and the total number of the samples as a denominator.

### (2) High Temperature High Humidity Storage Test

The solid state image pickup device 1 was stored in 85° C. and 85% RH environment. The Al electrodes 15 of the solid state image pickup element 14 were visually checked as to whether discoloration occurred or not after 500 and 1,000 hours. In Table 2, the cumulative sum of discolored solid state image pickup elements 14 is indicated as a numerator and the total number of the samples as a denominator.

Table 1 shows the THB test results in relation to the composition of the resin adhesive 20 and the Au—Al alloy ratio. Table 2 shows a relationship between the composition of the resin adhesive 20 and the number of samples in which the Al electrodes were corroded after the high temperature high humidity storage test.

TABLE 1

| | | | | | | Comparative | |
|---|---|---|---|---|---|---|---|
| | | Examples | | | | Examples | |
| | | 1 | 2 | 3 | 4 | 1 | 2 |
| Composition (wt %) | | | | | | | |
| Epoxy resin [A] | A-1 | 68.0 | 68.0 | 68.0 | 68.0 | 68.0 | 68.0 |
| Polymerization | B-1 | 4.8 | 4.8 | 4.8 | | | |
| initiator [B] | B-2 | | | | | 0.8 | |
| | B-3 | | | | | | 0.9 |
| | B-4 | | | | 4.7 | | |
| Organic peroxide [C] | C-1 | 0.1 | 0.1 | 0.1 | 0.1 | 0.1 | 0.1 |
| Filler [D] | D-1 | 27.1 | 27.1 | 27.1 | 27.2 | 31.1 | 31.0 |
| Au—Al alloy ratio | | 20.4 | 33.4 | 52.5 | 51.6 | 53.0 | 53.1 |
| (wt %) | | | | | | | |
| THB test result | | | | | | | |
| 200 h | | 0/24 | 0/24 | 0/24 | 0/24 | 0/24 | 0/24 |
| 400 h | | 0/24 | 0/24 | 0/24 | 0/24 | 1/24 | 0/24 |
| 600 h | | 0/24 | 0/24 | 0/24 | 0/24 | 3/24 | 0/24 |
| 800 h | | 0/24 | 0/24 | 0/24 | 0/24 | 11/24 | 0/24 |
| 1,000 h | | 1/24 | 0/24 | 0/24 | 0/24 | 23/24 | 0/24 |
| 1,200 h | | 4/24 | 1/24 | 0/24 | 0/24 | 24/24 | 0/24 |

TABLE 2

| | | | | Comparative | |
|---|---|---|---|---|---|
| | | Examples | | Examples | |
| | | 11 | 12 | 11 | 12 |
| Composition (wt %) | | | | | |
| Epoxy resin [A] | A-1 | 68.0 | 68.0 | 68.0 | 68.0 |
| Polymerization initiator [B] | B-1 | 4.8 | | | |
| | B-2 | | | 0.8 | |
| | B-3 | | | | 0.9 |
| | B-4 | | 4.7 | | |
| Organic peroxide [C] | C-1 | 0.1 | 0.1 | 0.1 | 0.1 |
| Filler [D] | D-1 | 27.1 | 27.2 | 31.1 | 31.0 |
| Au—Al alloy ratio (wt %) | | 52.5 | 51.5 | 31.1 | 31.0 |
| High temp. high humidity storage test | | | | | |

| | | | | | |
|---|---|---|---|---|---|
| 85° C. 85% RH | 500 h | 0/24 | 0/24 | 24/24 | 24/24 |
| | 1,000 h | 0/24 | 0/24 | 24/24 | 24/24 |

Next, the THB test results shown in Table 1 are described below.

### Example 2 and Comparative Example 1

In Example 2 and Comparative Example 1 shown in Table 1, the resin adhesives are different in composition, i.e., they contain different anions of onium salt in different amounts. The resin adhesive of Example 2 contains 4.8 wt % tetrakis(pentafluorophenyl)borate as the anion, while the resin adhesive of Comparative Example 1 contains 0.8 wt % hexafluoroantimonate as the anion.

In the THB test, none of the samples of Example 2 failed even after a lapse of 1,200 h. On the other hand, some of the samples of Comparative Example 1 failed after a lapse of 400 h and every sample failed in 1,200 h. Inspection of the failed parts showed that interfacial peeling was caused by the corrosion of the interface between the nail head 31 of the Au wire 16 and the Al electrode 15. A cause of this phenomenon is presumably the difference in anion structure, i.e., the difference in bond energy between fluorine and carbon.

### Examples 1 to 3

Examples 1 to 3 are different in Au—Al alloy ratio. The mechanical strength of the weld created by the nail head 31 of the Au wire 16 and the Al electrode 15 is dependent on the area of the Au—Al alloy. The higher the alloy ratio is, the better results are obtained in the THB test. However, it is necessary to raise stage temperature during the bonding in order to increase the alloy ratio, which is more likely to damage the on-chip lenses formed on the solid state image pickup element 14.

### Example 4 and Comparative Example 2

Both of the resin adhesives 20 of Example 4 and Comparative Example 2 shown in Table 1 contain an iodine-free polymerization initiator and triaryl sulfonium as a cation of the onium salt, but they contain different anions of onium salt in different amounts. The resin adhesive of Example 4 contains 4.8 wt % tetrakis(pentafluorophenyl)borate as the anion, while the resin adhesive of Comparative Example 2 contains 0.9 wt % hexafluoroantimonate as the anion. Although both of them showed good results in the THB test, their results were different in the high temperature high humidity storage test. The results of the high temperature high humidity storage test are described below with reference to Table 2.

### Examples 11-12 and Comparative Examples 11-12

The resin adhesive of Example 11 has the same composition as that of Example 1, while the resin adhesive of Example 12 has the same composition as that of Example 4. The resin adhesive of Comparative Example 11 has the same composition as that of Comparative Example 1, while the resin adhesive of Comparative Example 12 has the same composition as that of Comparative Example 2. The adhesives of Examples 11 and 12 contain tetrakis(pentafluorophenyl)borate as the anion of the onium salt, while the adhesives of Comparative Examples 11 and 12 contains hexafluoroantimonate as the anion of the onium salt. In the high temperature high humidity storage test, all the Al electrodes 15 of the solid state image pickup elements 14 were discolored in 500 h and the corrosion was observed in every sample of Comparative Examples 11 and 12. On the other hand, such failure was not observed in the samples of Examples 11 and 12.

### Second Embodiment

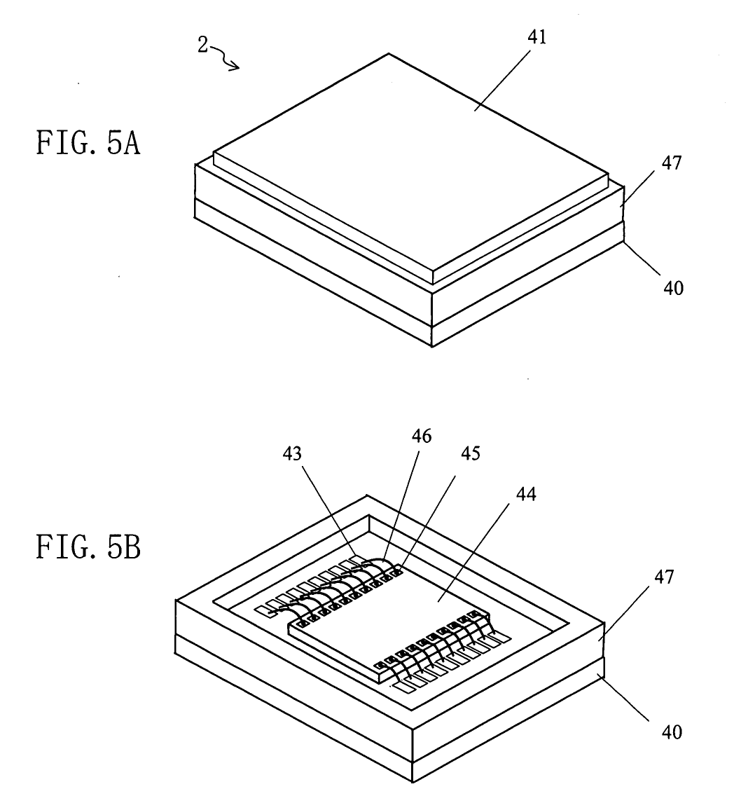

FIG. 5A is a schematic perspective view of a solid state image pickup device 2 of a second embodiment and FIG. 5B is a schematic perspective view of the solid state image pickup device 2 of FIG. 5A from which a transparent component 41 and a resin adhesive 50 are removed.

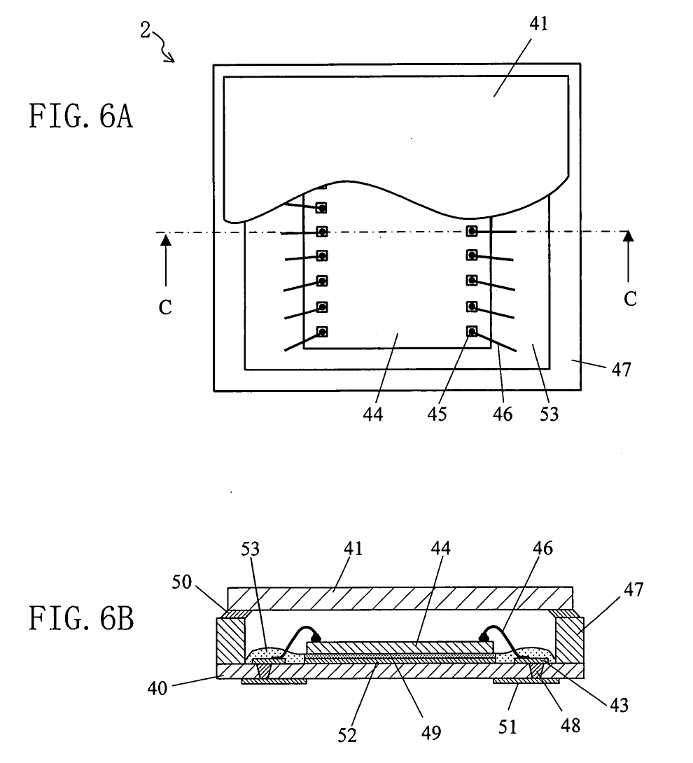

FIG. 6A is a schematic plan view of the solid state image pickup device 2 of the present embodiment and FIG. 6B is a sectional view taken along the line C-C of FIG. 6A.

The solid state image pickup device 2 of the present embodiment includes a substrate 40 having a rib 47 formed on the periphery thereof, a die pattern 52 formed on the middle of the substrate 40, a solid state image pickup element 44 bonded onto the die pattern 52 with a die bonding agent 49, Au wires 46 for electrically connecting connection terminals 43 formed on the substrate 40 and Al electrodes (bonding pads) 45 of the solid state image pickup element 44, an ion adsorbent 53 provided between the solid state image pickup element 44 and the rib 47, a transparent component 41 bonded onto the rib 47 to cover the solid state image pickup element 44 and a resin adhesive 50 sandwiched between the rib 47 and the transparent component 41.

On one of the surfaces of the substrate 40, a mount region for mounting the solid state image pickup element 44 is defined. The die pattern 52 is provided in the mount region and electrically connected to the solid state image pickup element 44. The plurality of connection terminals 43 are provided in a region of the substrate 40 between the mount region and a region for forming the rib 47. Conductive parts 48 penetrating the substrate 40 are provided such that they are connected to parts of the connection terminals 43 more outside than the joints with the Au wires 46. Further, external connection terminals 51 are formed on the other surface of the substrate 40 to be connected to the conductive parts 48. The connection terminals 43 are radially arranged with respect to the mount region.

The substrate 40 of the present embodiment is a resin substrate. Various kinds of resin substrates may be used. For example, a resin substrate may be prepared by immersing organic fiber such as glass fiber or Kevlar® with an epoxy resin, a phenol resin or a polyimide resin and curing the resin. Or alternatively, a BT resin substrate may be used. In the present embodiment, the BT resin substrate is used. Therefore, the substrate 40 is referred to as a resin substrate 40.

A copper foil is formed on the surface of the resin substrate 40 and patterned into desired shape by photolithography and etching.

For example, a copper foil of about 1.8 μm thickness is adhered onto both surfaces of the BT resin substrate 40 of about 0.2 mm thickness. After through holes are formed, a copper layer (not shown) is formed on the surface of the resin substrate 40 covered with the copper foil by a combined use of electroless plating and electroplating. During this time, the copper plating layer is formed on the inner surfaces of the through holes. Then, the die pattern 52, connection terminals 43, conductive parts 48 and external connection terminals 51 as shown in FIGS. 6A and 6B are formed by photolithography and etching. A thin gold film (not shown) is formed on the surfaces of the die pattern 52, connection terminals 43, conductive parts 48 and external connection terminals 51. The thin gold film is provided by forming a nickel plating layer on the copper pattern and forming a gold plating layer on the nickel plating layer. This configuration improves bondability in bonding the Au wires 46 to the connection terminals 43 and solder wettability of the external connection terminals 51. Thus, reliability at the joints is improved.

The rib 47 is a resin frame and easily obtained by molding a resin, such as a liquid crystal polymer, polyphenylenesulfide or polyethyleneterephthalate, and fixed onto the substrate 40 with a thermosetting resin adhesive (not shown). Alternatively, a plurality of resin substrates 40 connected to each other in the form of a sheet may be prepared in advance and the rib 47 may be formed thereon by transfer molding using a biphenyl epoxy resin or a phenol novolac epoxy resin, followed by dicing the sheet into individual substrates.

The die bonding agent 49 may be made of thermosetting resin paste such as an epoxy resin or a polyimide resin, or an adhesive tape. If high heat transfer property is required, it is preferable to use resin paste with a metallic filler such as Ag dispersed therein.

The resin adhesive 50 may be a thermosetting resin or a UV curable resin. The UV curable resin is preferable because it is less likely to cause thermal damage to the solid state image pickup element, especially to the on-chip lenses formed in an image pickup region of the solid state image pickup element 44, and reduces time for curing the resin adhesive and cycle time of the manufacture.

The ion adsorbent 53 may be a fluid epoxy resin mixed with a filler such as calcium peroxide or hydrotalcite. Preferable examples of the fluid epoxy resin include bisphenol epoxy resins, novolac epoxy resins and biphenyl epoxy resins. Among the bisphenol epoxy resins, a bisphenol A epoxy resin, a bisphenol S epoxy resin and a bisphenol F resin are preferable and generally used because they are in the liquid state at room temperature. The ion adsorbent 53 may be contained in the die bonding agent.

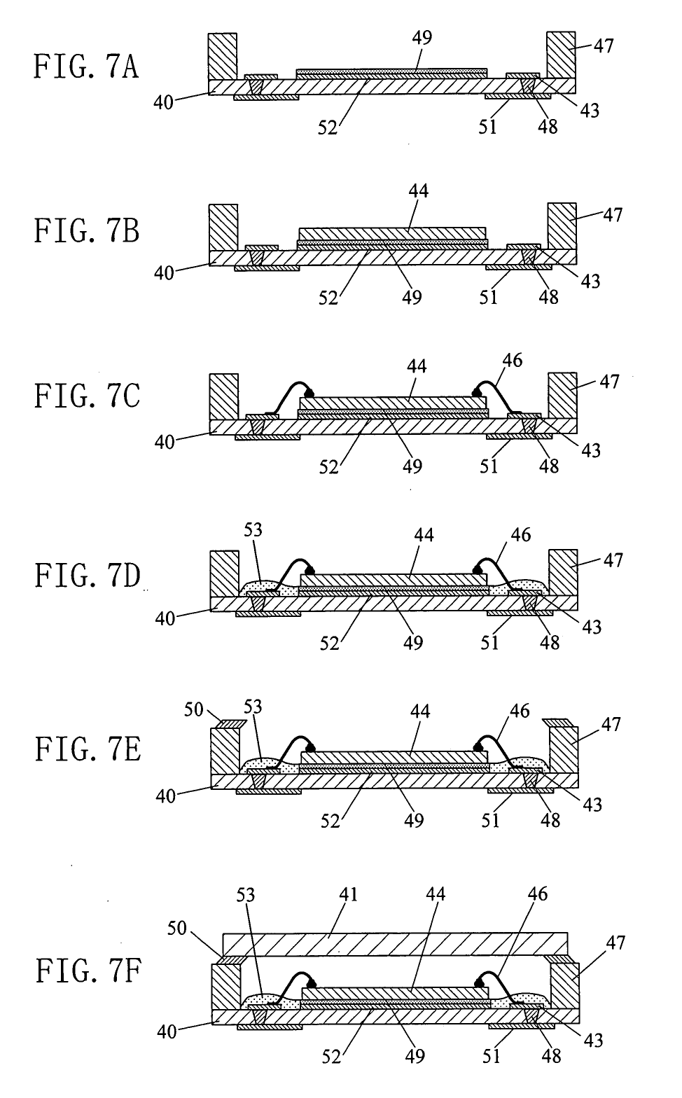

Hereinafter, brief explanation of a method for manufacturing the solid state image pickup device 2 of the present embodiment is provided with reference to FIGS. 7A to 7F.

Referring to FIG. 7A, a die bonding agent 49 is applied to the die pattern 52 of the resin substrate 40 using a dispenser. The dispenser may have a single nozzle or multiple nozzles. The die bonding agent 49 may be provided by a transfer method. The die bonding agent 49 may be thermosetting paste containing a thermosetting resin such as an epoxy resin or a polyimide resin as a main ingredient. The epoxy resin may preferably be bisphenol epoxy resins, novolac epoxy resins or biphenyl epoxy resins. Among the bisphenol epoxy resins, a bisphenol A epoxy resin, a bisphenol S epoxy resin and a bisphenol F epoxy resin are preferable and generally used because they are in the liquid state at room temperature. If high heat transfer property is required, it is preferable to use resin paste with a metallic filler such as Ag dispersed therein. The thermosetting resin paste may be replaced with an adhesive tape. The adhesive tape is bonded to the rear surface of a wafer before separating the solid state image pickup elements 44 by dicing such that it is cut together with the solid state image pickup elements. In this way, the solid state image pickup elements are provided with the adhesive tape bonded to the rear surface.

As shown in FIG. 7B, the solid state image pickup element 44 is placed on the die pattern 52 of the resin substrate 40. This is stored in a thermosetting oven at about 120 to 170° C. for 2 hours such that the die bonding agent 49 is cured by heat. The thermal curing may preferably be carried out in nitrogen atmosphere from the aspect of preventing surface oxidation of the Al electrodes 45 of the solid state image pickup element 44.

Then, as shown in FIG. 7C, the Al electrodes 45 of the solid state image pickup element 44 are connected to the connection terminals 43 of the substrate 40 with the Au wires 46 by ball bonding. The connection may be achieved by wedge bonding instead of the ball bonding and the Au wires 46 may be replaced with Al or Cu wires. In this way, the Al electrodes 45 of the solid state image pickup element 44, Au wires 46, connection terminals 43, conductive parts 48 and external bottom electrodes 51 are electrically connected.

Then, as shown in FIG. 7D, an ion adsorbent 53 is applied to a region between the rib 47 and the solid state image pickup element 44. The ion adsorbent 53 may be thermally cured. Since the ion adsorbent 53 is capable of adsorbing ions liberated from the resin adhesive 50, the reliability of the solid state image pickup element 44 is improved.

Then, as shown in FIG. 7E, the resin adhesive 50 is applied onto the rib 47 using a dispenser.

Then, as shown in FIG. 7F, a transparent component 41 is placed on the rib 47 to cover the solid state image pickup element 44 bonded to the die pattern 52 of the resin substrate 40.

Subsequently, preliminary heating is carried out under certain conditions to temporarily fix the transparent component 41 onto the rib 47 and then the top surface of the transparent component 41 is irradiated with UV light. The UV irradiation initiates the polymerization of the resin adhesive 50, thereby curing the resin adhesive 50 and bonding the transparent component 41 to the rib 47. The UV light preferably has a wavelength of 300 nm or higher and illumination of 200 mW or higher.

In the present embodiment, the resin substrate 40 may be replaced with a ceramic substrate. Alternatively, a cavity is formed in the middle of the resin substrate 40 and the solid state image pickup element 44 may be placed on the bottom thereof.

### Third Embodiment

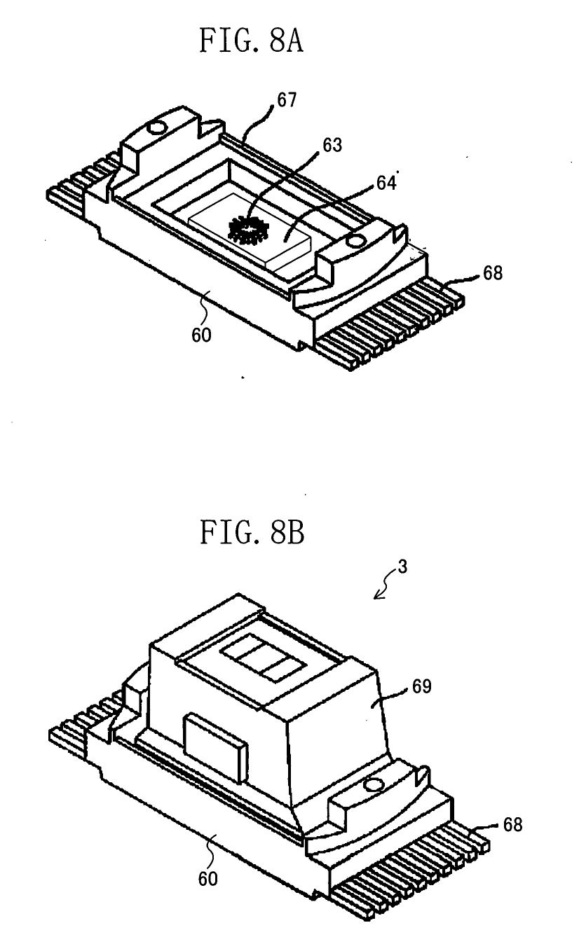

A semiconductor device of a third embodiment is a hologram unit 3 shown in FIGS. 8A and 8B. The hologram unit 3 is provided with semiconductor elements, i.e., a light receiving element 64 having a light receiving region as an active region and a laser element 63 having a light emitting region as an active region. These semiconductor elements are placed in a recess formed in a substrate 60. Connection terminals formed on the substrate 60 and bonding pads of the semiconductor elements are connected to each other with Au wires. The substrate 60 is a combination of a resin housing and a lead frame including die pads and leads. A rib 67 is formed on the top surface of a sidewall of the substrate that defines the recess such that an adhesive for bonding a cover 69 to the top surface of the sidewall does not spill over onto the outer surface of the sidewall. Further, external leads 68 are configured to protrude from part of the outer wall of the substrate 60 for external connection.

In the hologram unit 3 of the present embodiment, the cover 69 for covering the recess in the substrate 60 including the light receiving element 64 and the laser element 63 is bonded to the substrate 60 with a resin adhesive. The cover 69 is a transparent hologram capable of selectively refracting light of a certain wavelength when it passes through the cover 69.

The resin adhesive for bonding the substrate 60 and the cover 69 is the same as that used in the first embodiment. With use of the resin adhesive, an alloy layer formed on the interface between the Au wires and the Al electrodes of the semiconductor element is prevented from corrosion. Therefore, the semiconductor device is provided with high reliability.

### Fourth Embodiment

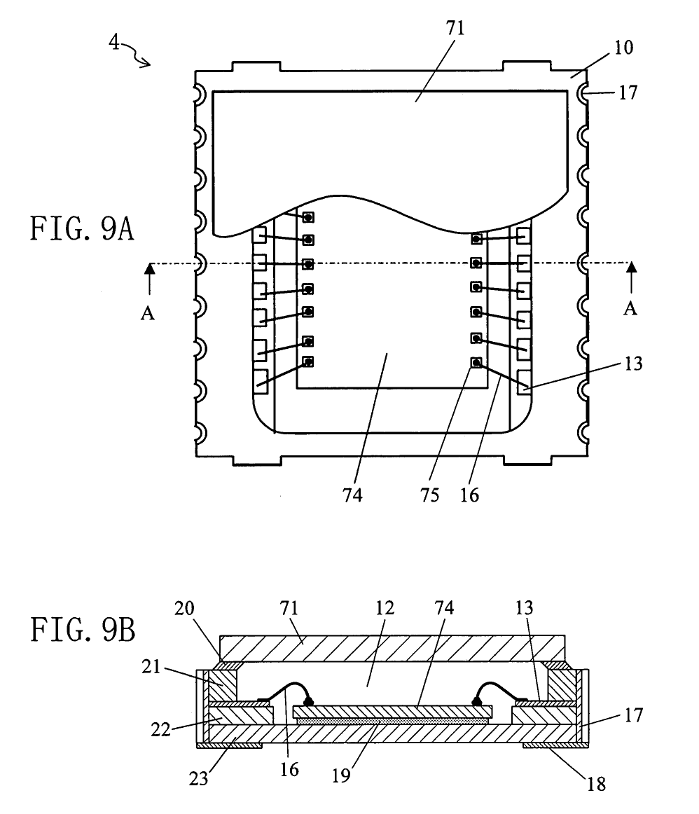

A semiconductor device 4 of a fourth embodiment shown in FIGS. 9A and 9B has the same structure as the solid state image pickup device of the first embodiment except that a pressure sensor element 74 is mounted on the substrate 10 as a semiconductor element instead of the solid state image pickup element. With this structure, the connection between the bonding wires 16 and electrodes 75 of the semiconductor element is achieved with high reliability under high temperature and high humidity conditions. In the present embodiment, a cover 71 need not be transparent and various kinds of material may be used for the cover 71, such as metal, plastic and ceramic.

### Fifth Embodiment

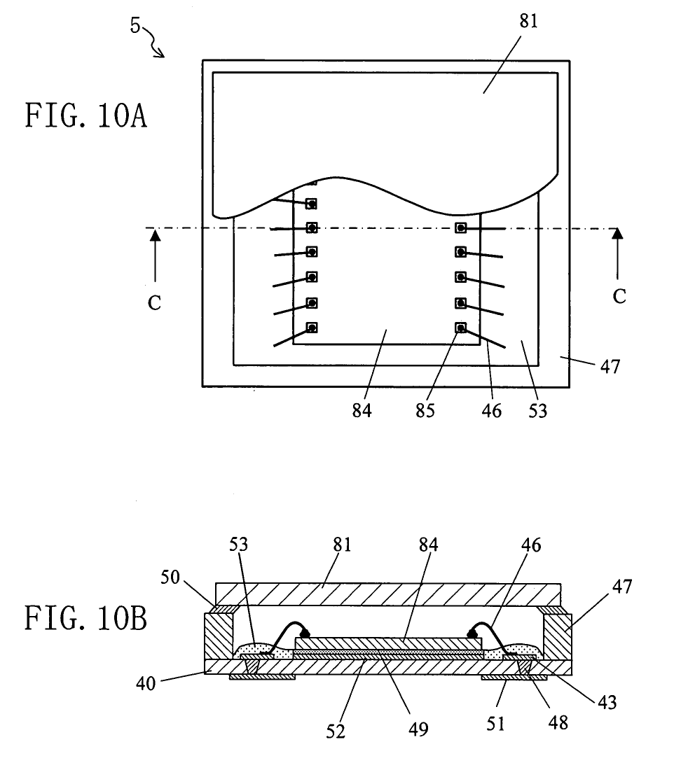

A semiconductor device 5 of a fifth embodiment shown in FIGS. 10A and 10B has the same structure as the solid state image pickup device of the second embodiment except that an acceleration sensor element 84 is mounted on the substrate 40 as a semiconductor element instead of the solid state image pickup element. With this structure, the connection between the bonding wires 46 and electrodes 85 of the semiconductor element is achieved with high reliability under high temperature and high humidity conditions. In the present embodiment, a cover 81 need not be transparent and various kinds of material may be used for the cover 81, such as metal, plastic and ceramic.

### Other Embodiments

The foregoing embodiments are described merely for the explanation of the present invention and the invention is not limited thereto. In the first and second embodiments, the solid state image pickup element used as the semiconductor element may be replaced with another light receiving element such as a photodiode, an LED or a laser light emitting element.

A sound sensor element, a pressure sensor element and an acceleration sensor element are also contained in the housing and enclosed therein not to have influence from outside. These sensors may be used as the semiconductor elements in the above-described embodiments. In this case, the cover need not be transparent. The active regions of the sound sensor element, pressure sensor element and acceleration sensor element are semiconductor regions that functions as sensors.

According to the solid state image pickup device of the present invention, an alloy layer formed on the interface between Au wires and Al electrodes of the solid state image pickup element is prevented from corrosion. Therefore, the solid state image pickup device is provided with improved reliability.

What is claimed is:

1. A solid state image pickup device comprising:
a solid state image pickup element including an image pickup region and a plurality of bonding pads;
a substrate having a recess and containing the solid state image pickup element;
a plurality of connection terminals formed in the recess of the substrate;
Au wires for electrically connecting the bonding pads and the connection terminals;
a transparent component placed on a top surface of the substrate; and
a resin adhesive for bonding the substrate and the transparent component, wherein
the resin adhesive contains an epoxy resin, a polymerization initiator and organic peroxide and the polymerization initiator contains onium salt having a halogen-containing aromatic compound as an anion.

2. A solid state image pickup device comprising:
a solid state image pickup element including an image pickup region and a plurality of bonding pads;
a substrate on which the solid state image pickup element is mounted;
a rib formed on the substrate;
a plurality of connection terminals formed on the substrate;
Au wires for electrically connecting the bonding pads and the connection terminals;
a transparent component placed above the substrate and bonded to a top surface of the rib; and
a resin adhesive for bonding the top surface of the rib and the transparent component, wherein
the resin adhesive contains an epoxy resin, a polymerization initiator and organic peroxide and the polymerization initiator contains onium salt having a halogen-containing aromatic compound as an anion.

3. The solid state image pickup device of claim 1, wherein the halogen-containing aromatic compound is a fluorine-containing aromatic compound.

4. The solid state image pickup device of claim 2, wherein the halogen-containing aromatic compound is a fluorine-containing aromatic compound.

5. The solid state image pickup device of claim 1, wherein the halogen-containing aromatic compound is a borate compound.

6. The solid state image pickup device of claim 2, wherein the halogen-containing aromatic compound is a borate compound.

7. The solid state image pickup device of claim 1, wherein the content of the polymerization initiator is higher than 0.5 wt % and less than 7 wt %.

8. The solid state image pickup device of claim 2, wherein the content of the polymerization initiator is higher than 0.5 wt % and less than 7 wt %.

9. The solid state image pickup device of claim 1, wherein
the bonding pads of the solid state image pickup element are Al electrodes and
the ratio of an alloy formed on an interface between the Au wires and the Al electrodes is 50% or higher.

10. The solid state image pickup device of claim 2, wherein
the bonding pads of the solid state image pickup element are Al electrodes and
the ratio of an alloy formed on an interface between the Au wires and the Al electrodes is 50% or higher.

11. The solid state image pickup device of claim 1, wherein the substrate is a ceramic substrate.

12. The solid state image pickup device of claim 2, wherein the substrate is a ceramic substrate.

13. The solid state image pickup device of claim 1, wherein the substrate is a resin substrate.

14. The solid state image pickup device of claim 2, wherein the substrate is a resin substrate.

15. The solid state image pickup device of claim 1, wherein an ion adsorbent is placed in the recess of the substrate.

16. The solid state image pickup device of claim 2, wherein an ion adsorbent is placed in a region enclosed with the top surface of the substrate and the rib.

17. A method for manufacturing a solid state image pickup device comprising the steps of:
mounting a solid state image pickup element including an image pickup region and a plurality of bonding pads on a substrate having a recess;
forming connection terminals on the substrate;
electrically connecting the bonding pads of the solid state image pickup element and the connection terminals on the substrate with Au wires;
applying a resin adhesive containing onium salt having a halogen-containing aromatic compound as an anion onto a top surface of the substrate; and
placing a transparent component on the top surface of the substrate and irradiating a top surface of the transparent component with UV light to cure the resin adhesive.

18. A method for manufacturing a solid state image pickup device comprising the steps of:
mounting a solid state image pickup element including an image pickup region and a plurality of bonding pads on a substrate;
forming connection terminals on the substrate;
electrically connecting the bonding pads of the solid state image pickup element and the connection terminals on the substrate with Au wires;
forming a rib in the form of a frame on the substrate;
applying a resin adhesive containing onium salt having a halogen-containing aromatic compound as an anion onto a top surface of the rib; and
placing a transparent component on the top surface of the rib and irradiating a top surface of the transparent component with UV light to cure the resin adhesive.

19. A semiconductor device comprising:
a semiconductor element including an active region and a plurality of bonding pads;
a substrate having a recess and containing the semiconductor element;
a plurality of connection terminals formed in the recess of the substrate;
Au wires for electrically connecting the bonding pads and the connection terminals;
a cover placed on a top surface of the substrate; and
a resin adhesive for bonding the substrate and the cover, wherein
the resin adhesive contains an epoxy resin, a polymerization initiator and organic peroxide and the polymerization initiator contains onium salt having a halogen-containing aromatic compound as an anion.

20. A semiconductor device comprising:
a semiconductor element including an active region and a plurality of bonding pads;
a substrate on which the semiconductor element is mounted;
a rib formed on the substrate;
a plurality of connection terminals formed on the substrate;
Au wires for electrically connecting the bonding pads and the connection terminals;
a cover placed above the substrate and bonded to a top surface of the rib; and
a resin adhesive for bonding the top surface of the rib and the transparent component, wherein
the resin adhesive contains an epoxy resin, a polymerization initiator and organic peroxide and the polymerization initiator contains onium salt having a halogen-containing aromatic compound as an anion.

21. The semiconductor device of claim 19, wherein the halogen-containing aromatic compound is a fluorine-containing aromatic compound.

22. The semiconductor device of claim 20, wherein the halogen-containing aromatic compound is a fluorine-containing aromatic compound.

23. The semiconductor device of claim 19, wherein the halogen-containing aromatic compound is a borate compound.

24. The semiconductor device of claim 20, wherein the halogen-containing aromatic compound is a borate compound.

25. The semiconductor device of claim 19, wherein the content of the polymerization initiator is higher than 0.5 wt % and less than 7 wt %.

26. The semiconductor device of claim 20, wherein the content of the polymerization initiator is higher than 0.5 wt % and less than 7 wt %.

27. The semiconductor device of claim 19, wherein
the bonding pads of the semiconductor element are Al electrodes and
the ratio of an alloy formed on an interface between the Au wires and the Al electrodes is 50% or higher.

28. The semiconductor device of claim 20, wherein
the bonding pads of the semiconductor element are Al electrodes and
the ratio of an alloy formed on an interface between the Au wires and the Al electrodes is 50% or higher.

29. The semiconductor device of claim 19, wherein the substrate is a ceramic substrate.

30. The semiconductor device of claim 20, wherein the substrate is a ceramic substrate.

31. The semiconductor device of claim 19, wherein the substrate is a resin substrate.

32. The semiconductor device of claim 20, wherein the substrate is a resin substrate.

33. The semiconductor device of claim 19, wherein an ion adsorbent is placed in the recess of the substrate.

34. The semiconductor device of claim 20, wherein an ion adsorbent is placed in a region enclosed with the top surface of the substrate and the rib.

35. The semiconductor device of claim 19, wherein the semiconductor element is a sound sensor element, a pressure sensor element or an acceleration sensor element.

36. The semiconductor device of claim 20, wherein the semiconductor element is a sound sensor element, a pressure sensor element or an acceleration sensor element.

37. The semiconductor device of claim 19, wherein the semiconductor element is a laser element, an LED or a photodiode and the cover is a transparent component.

38. The semiconductor device of claim 20, wherein the semiconductor element is a laser element, an LED or a photodiode and the cover is a transparent component.

39. A method for manufacturing a semiconductor device comprising the steps of:
mounting a semiconductor element including an active region and a plurality of bonding pads on a substrate having a recess;
forming connection terminals on the substrate;
electrically connecting the bonding pads of the semiconductor element and the connection terminals on the substrate with Au wires;
applying a resin adhesive containing onium salt having a halogen-containing aromatic compound as an anion onto a top surface of the substrate; and
placing a cover on the top surface of the substrate and irradiating a top surface of the cover with UV light to cure the resin adhesive.

40. A method for manufacturing a semiconductor device comprising the steps of:
mounting a semiconductor element including an active region and a plurality of bonding pads on a substrate;
forming connection terminals on the substrate;
electrically connecting the bonding pads of the semiconductor element and the connection terminals on the substrate with Au wires;
forming a rib in the form of a frame on the substrate;
applying a resin adhesive containing onium salt having a halogen-containing aromatic compound as an anion onto a top surface of the rib; and
placing a cover on the top surface of the rib and irradiating a top surface of the cover with UV light to cure the resin adhesive.

41. The method of claim 39, wherein the semiconductor element is a laser element, an LED or a photodiode and the cover is a transparent component.

42. The method of claim 40, wherein the semiconductor element is a laser element, an LED or a photodiode and the cover is a transparent component.

43. A solid state image pickup device comprising:
a solid state image pickup element including an image pickup region and a plurality of bonding pads;
a substrate having a recess and containing the solid state image pickup element;
a plurality of connection terminals formed in the recess of the substrate;
Au wires for electrically connecting the bonding pads and the connection terminals;
a transparent component placed on a top surface of the substrate; and
a resin adhesive for bonding the substrate and the transparent component, wherein
the resin adhesive contains an epoxy resin and a polymerization initiator and the polymerization initiator contains onium salt having a halogen-containing aromatic compound as an anion.

44. A solid state image pickup device comprising:
a solid state image pickup element including an image pickup region and a plurality of bonding pads;
a substrate on which the solid state image pickup element is mounted;
a rib formed on the substrate;
a plurality of connection terminals formed on the substrate;
Au wires for electrically connecting the bonding pads and the connection terminals;
a transparent component placed above the substrate and bonded to a top surface of the rib; and
a resin adhesive for bonding the top surface of the rib and the transparent component, wherein
the resin adhesive contains an epoxy resin and a polymerization initiator and the polymerization initiator contains onium salt having a halogen-containing aromatic compound as an anion.

45. A semiconductor device comprising:
a semiconductor element including an active region and a plurality of bonding pads;
a substrate having a recess and containing the semiconductor element;
a plurality of connection terminals formed in the recess of the substrate;
Au wires for electrically connecting the bonding pads and the connection terminals;
a cover placed on a top surface of the substrate; and
a resin adhesive for bonding the substrate and the cover, wherein
the resin adhesive contains an epoxy resin and a polymerization initiator and the polymerization initiator contains onium salt having a halogen-containing aromatic compound as an anion.

46. A semiconductor device comprising:
a semiconductor element including an active region and a plurality of bonding pads;
a substrate on which the semiconductor element is mounted;
a rib formed on the substrate;
a plurality of connection terminals formed on the substrate;
Au wires for electrically connecting the bonding pads and the connection terminals;
a cover placed above the substrate and bonded to a top surface of the rib; and
a resin adhesive for bonding the top surface of the rib and the cover, wherein
the resin adhesive contains an epoxy resin and a polymerization initiator and the polymerization initiator contains onium salt having a halogen-containing aromatic compound as an anion.
